(19) United States
(12) Patent Application Publication
(10) Pub. No.: US 2002/0102827 A1
(43) Pub. Date: Aug. 1, 2002

(54) Method for controlling multiple gate oxide growing by argon plasma doping

(76) Inventor: Wei-Wen Chen, Hsinchu (TW)

Correspondence Address: POWELL, GOLDSTEIN, FRAZER & MURPHY LLP, P.O. BOX 97223, WASHINGTON, DC, 20090-7223, US

(21) Appl. No.: 09/795,935

(22) Filed: Feb. 28, 2001

(30) Foreign Application Priority Data
Jan. 30, 2001 (TW) 90101833

(51) Int. Cl. H01L 21/8234

(52) U.S. Cl. 438/584

(57) ABSTRACT

A method for controlling multiple gate oxide growing by argon plasma doping. An argon plasma doping process is utilized to dope argon ions into the surface layer in the channel region of semiconductor substrate. A thermal oxidation step is then performed to form a gate oxide layer on the semiconductor substrate. Since argon ions doping will increase growing thickness of gate oxide, multiple thickness of gate oxide can be produced in one thermal oxidation step by doping different dosage of argon ions in each channel region. Accordingly, using of thermal oxidation step is decreased to shorten process time and therefore increases throughput.

### FIELD OF THE INVENTION

The present invention relates to a method of fabricating semiconductor device, and more particular to a method for controlling multiple gate oxide growing by argon plasma doing, wherein multiple thickness of gate oxide can be grew in one thermal oxidation.

### BACKGROUND OF THE INVENTION

Very Large Scale Integration (VLSI) is composed of a lot of metal-oxide-semiconductor (MOS) transistors connected with interconnects on a semiconductor substrate. While critical dimension is scaling down to 0.18 μm with fabricating technology improving, it is important for next generation to reduce process steps to form complex and stable semiconductor devices, for example, multiple gate transistors like CMOS transistor.

A thermal oxidation process by furnace is recently adopted for forming gate oxide layer of multiple gate transistors. However, the oxidation process needs 6-7 hours to finish a batch of process to form a gate oxide layer with desired thickness. In traditional, method of fabricating multiple thickness of gate oxide layer is performed by forming a patterned photoresist layer over the semiconductor substrate to expose the oxidation region, and then one thermal oxidation process is followed to grow the gate oxide layer with desired thickness. Likewise, above process of growing gate oxide layer is performed sequently to form other gate oxide layers with different thickness. Accordingly, two thermal oxidation processes are needed for dual gate transistors, and three thermal oxidation processes are needed for triple gate transistors. Similarly, multiple thermal oxidation processes are used in fabricating multiple gate transistors. Hence, thermal oxidation process becomes critical process for fabricating complex semiconductor device with multiple transistors, and directly affects throughput of manufacture.

### SUMMARY OF THE INVENTION

Therefore, the present invention provides a method for controlling multiple gate oxide growing by argon plasma doping, comprising the following steps. A semiconductor substrate having at least two channel regions is provided. A patterned photoresist layer is formed over the semiconductor substrate to expose one of the channel regions. An argon plasma doping step is performed to dope argon ions into the surface layer in the exposed channel region. The patterned photoresist layer is then removed. A thermal oxidation step is performed to form a gate oxide layer on the semiconductor substrate.

Since argon ions, which can increase thickness of growing gate oxide layer, are doped into the channel regions, only one thermal oxidation process is used in the present invention to grow gate oxide layer having multiple thickness in each channel region. Therefore, using of thermal oxidation process is decreased and time for produce gate oxide layer is shortened and thus increases throughput.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A-1C are schematic, cross-sectional views of one preferred embodiment of the present invention;

FIG. 2 is a schematic view of equipment structure of argon plasma doping; and

FIG. 3 shows relation of thickness of gate oxide corresponding with dosage of argon ions.

### DETAILED DESCRIPTION OF THE PREFERRED EMBODIMENT

The present invention discloses a method for controlling multiple gate oxide growing by argon plasma doping. Different dosages of argon ions are doped into each channel region for growing gate oxide layer with desired thickness in each channel region. Only one thermal oxidation process is used in the present invention to grow the gate oxide layer with multiple thickness in each channel region, so that shortens fabricating time and thus increases throughput.

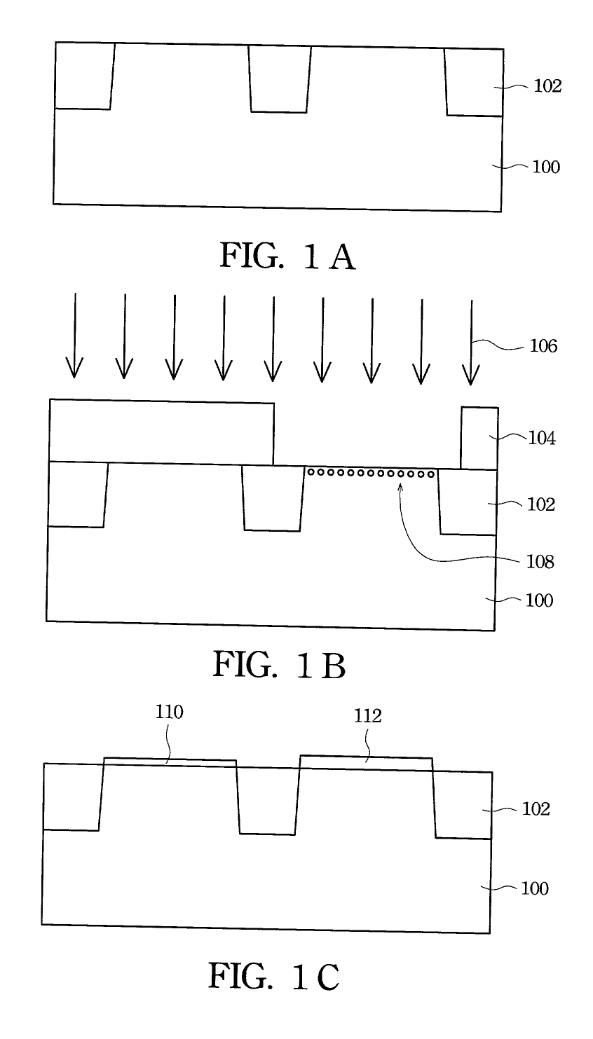

Referring to FIG. 1, a semiconductor substrate 100, such as single crystal silicon substrate is provided. A plurality of device isolations 102 are then formed in the substrate 100 to scheme locations of transistors in active regions between device isolations 102, wherein the active region comprise channel regions of each transistor. The device isolations 102 comprise the local oxidation of silicon (LOCOS) structures or shallow trench isolations (STI).

Referring to FIG. 1B, a photoresist layer is formed over the substrate 100, and then conventional lithography technology, such as exposing and developing steps etc., is used to pattern the photoresist layer 104 to expose the channel region subsequently doping with argon ions. An argon plasma doping step 106 is performed by utilizing argon plasma to pulsed dope argon ions into the surface layer in the active regions (comprising channel regions). The argon plasma doping of the present invention can get less doping depth, such as shallower than 50 ANG., so that most of doped argon ions are stayed in the surface layer of the substrate 100 and less damages the surface of the substrate 100. Hence, this is rewarding to maintain perfection of interface between the substrate 100 and the gate oxide layer subsequently formed on the substrate 100. The patterned photoresist layer 104 is then removed.

Above steps of formation of photoresist layer and argon plasma doping is repeated according amounts of multiple thickness of the gate oxide layer. If nth different thickness of gate oxide layer is desired, repeats above steps of formation of photoresist layer and argon plasma doping for (n−1) times. In sequence, nth dosage of argon ions is doped into nth channel region of the substrate 100. For example, if n=2, above steps is repeated for one times to dope second dosage of argon ions into second channel region so that three degrees of dosages (0-2th degrees) of argon ions are formed. Wherein, the range of n, such as about 2-10 times, is adjusted in accordance with the multiple degrees of thickness of gate oxide layer, and over 10 times if needed, not limited herein.

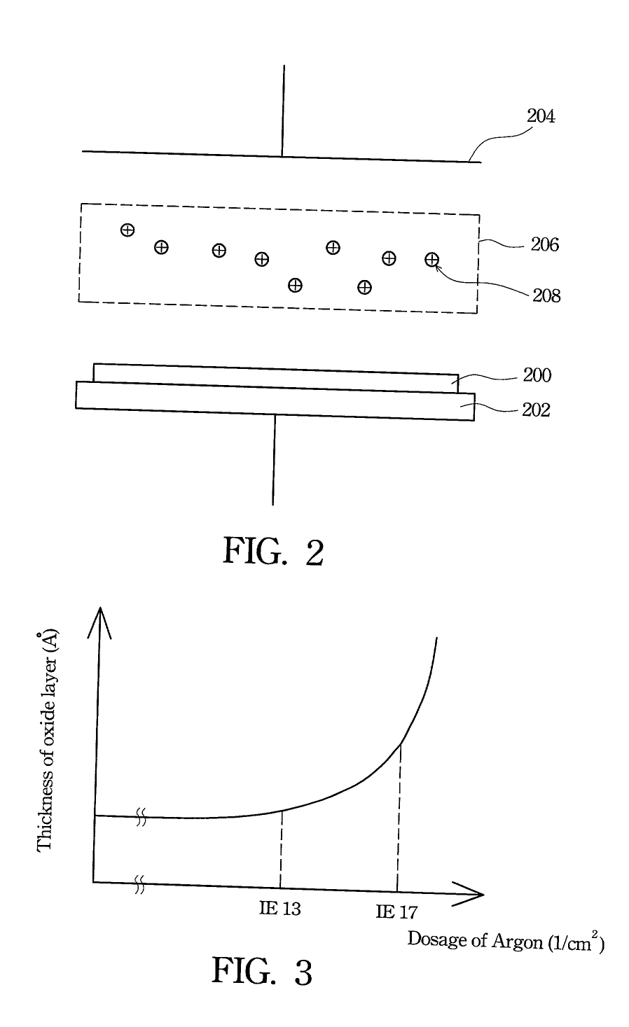

The argon plasma doping is further described in detail in the following description. Referring to FIG. 2, it is a schematic view of equipment structure of argon plasma doping. The reaction chamber in the equipment mainly comprises a lower electrode 202 and an upper electrode 204, and a wafer 200 comprising the semiconductor substrate 100 is deposed and mounted on the lower electrode 202. An argon gas is injected into the reaction chamber and flowed between the lower and upper electrode 202, 204. A negative voltage is applied on the lower electrode 202 in accompany with a positive voltage applied on the upper electrode 204 to make argon gas decompose to generate plasma 206 with positive argon ions 208. The positive argon ions 208 are then attracted with the negative lower electrode 202 and move forward to be implanted into the wafer 200. In the preferred embodiment, pulsed voltage is applied on the lower electrode 202 to control the plasma. The process parameters in the argon plasma doping process are controlled in the following ranges. The energy of argon plasma doping is about 200-10000 eV, and the dosage of argon ions is about 1E13-1E17/cm², and preferably is about 1E15-1E16/cm². Suitable operating in accordance with other parameters, such as gas species, gas pressure, gas flow rate, voltage bias, distance between lower and upper electrode 202, 204, and reaction time, this can make better doping resulting.

Referring to FIG. 1C, a thermal oxidation step is then performed by utilizing traditional thermal oxidation, such as dry oxidation, at a temperature of about 750-900° C. with injecting pure oxygen, i.e. purity is about 100%, to oxidize the silicon substrate 100, and therefore gate oxide layers 110, 112 of silicon dioxide is grew on the substrate 100. Since the argon ions are doped into the surface layer of the substrate 100 prior to the thermal oxidation step, the thickness of gate oxide layer in the channel region doped with argon ions is thicker than the gate oxide layer in the channel region without argon ions. Therefore, in preferred embodiment of the present invention, different thickness of the gate oxide layers can be formed in one thermal oxidation step. For dual gate, two degrees of thickness are formed in the thermal oxidation process by doping argon ions for one times. Similarly, for triple gate, three degrees of thickness are formed in the thermal oxidation process by doping argon ions for two times.

Referring to FIG. 3, it shows relation of thickness of gate oxide corresponding with dosage of argon ions. The thickness of the gate oxide layer is proportional to the dosage of the doped argon ions. The growing thickness of the gate oxide layer is accordance with the dosage of the doped argon ions. For desired thickness of the gate oxide layer, the required dosage of doped argon ions can be derived by experiment data. The dosage of doped argon ions used in the semiconductor process is about 1E13-1E17/cm², but not limited herein, if the process requires.

According to above description, the present invention discloses a method for controlling gate oxide growing by argon plasma doping. By doping argon ions into each channel region, only one thermal oxidation process is used in the present invention, and gate oxide layer having multiple thickness in each channel region is grew. Therefore, time for growing gate oxide layer is shortened, and thus increases throughput of process.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method for controlling multiple gate oxide growing by argon plasma doping, comprising the steps of:
providing a semiconductor substrate having at least two channel regions;
forming a patterned photoresist layer over the semiconductor substrate to expose one of the channel regions;
performing an argon plasma doping step to dope argon ions into the surface layer in the exposed channel region;
removing the patterned photoresist layer; and
performing a thermal oxidation step to form a gate oxide layer on the semiconductor substrate.

2. The method according to claim 1, wherein the energy used in the argon plasma doping step is about 200-10000 eV.

3. The method according to claim 1, wherein the dosage of argon ions doped into the surface layer in the exposed channel region is about 1E15-1E16/cm².

4. The method according to claim 1, wherein pure oxygen is injected in the thermal oxidation step.

5. The method according to claim 1, wherein the thermal oxidation step is performed at a temperature of about 750-900° C.

6. The method according to claim 1, wherein the thickness of gate oxide layer in the channel region doped with argon ions is thicker than the gate oxide layer in the channel region without argon ions.

7. A method for controlling multiple gate oxide growing by argon plasma doping, comprising the steps of:
a) providing a semiconductor substrate having at least two channel regions;
b) forming a patterned photoresist layer over the semiconductor substrate to expose one of the channel regions;
c) performing an argon plasma doping step to dope argon ions into the surface layer in the exposed channel region;
d) removing the patterned photoresist layer;
e) repeating steps (b)-(d) for (n−1) times to dope nth dosage of argon ions in the nth channel region; and
f) performing a thermal oxidation step to form a gate oxide layer on the semiconductor substrate.

8. The method according to claim 7, wherein the energy used in the argon plasma doping step is about 200-10000 eV.

9. The method according to claim 7, wherein the dosage of argon ions doped into the surface layer in the exposed channel region is about 1E15-1E16/cm².

10. The method according to claim 7, wherein n is at the range of about 2-10.

11. The method according to claim 7, wherein pure oxygen is injected in the thermal oxidation step.

12. The method according to claim 7, wherein the thermal oxidation step is performed at a temperature of about 750-900° C.

13. The method according to claim 7, wherein the thickness of gate oxide layer in the channel region is increased corresponding with the dosage of argon ions doped in the channel region.
